(19) United States
(12) Patent Application Publication
(10) Pub. No.: US 2026/0276924 A1
(43) Pub. Date: Sep. 17, 2026

(54) OPTICAL MODULE

(71) Applicant: HISENSE BROADBAND MULTIMEDIA TECHNOLOGIES CO., LTD., Qingdao (CN)

(72) Inventors: Lilin HOU, Qingdao (CN); Xueyang WANG, Qingdao (CN); Liang SHI, Qingdao (CN); Chenghao JIN, Qingdao (CN); Yonghui WANG, Qingdao (CN)

(21) Appl. No.: 19/668,309

(22) Filed: May 5, 2026

Related U.S. Application Data
(63) Continuation of application No. PCT/CN2024/081995, filed on Mar. 15, 2024.

(30) Foreign Application Priority Data
Nov. 6, 2023 (CN) 202322983602.0
Nov. 6, 2023 (CN) 202322988901.3
Nov. 9, 2023 (CN) 202311490528.7

(51) Int. Cl. G02B 6/42

(52) U.S. Cl. CPC G02B 6/428; G02B 6/4214; G02B 6/4261; G02B 6/4278

(57) ABSTRACT

Provided in the present disclosure is an optical module, including: an upper conductive layer, a lower conductive layer, and an intermediate conductive layer on a circuit board. The upper conductive layer is provided with a first power supply pin, a second power supply pin, and a dummy pin. The intermediate conductive layer is provided with a power supply line. A third through hole is formed below the second power supply pin, and a first through hole is formed below the dummy pin. The third through hole and the first through hole are respectively connected to the power supply line. The present disclosure can prevent secondary power-on.

### CROSS-REFERENCE TO RELATED APPLICATIONS

The present disclosure is a continuation of International Application No. PCT/CN2024/081995, filed on Mar 15, 2024, which claims priority to Chinese Patent Application No. 202311490528.7, filed with the China National Intellectual Property Administration on Nov 9, 2023, priority to Chinese Patent Application No. 202322988901.3, filed with the China National Intellectual Property Administration on Nov 6, 2023, and priority to Chinese Patent Application No. 202322983602.0, filed with the China National Intellectual Property Administration on Nov 6, 2023. The entire contents of all above-mentioned applications are incorporated herein by reference.

### FIELD OF THE INVENTION

The present disclosure relates to the field of optical fiber communication technology, and in particular, to an optical module.

### BACKGROUND OF THE INVENTION

With the development of new services and application models such as cloud computing, mobile Internet, and video, advances in optical communication technology have become increasingly important. In optical communication technology, the optical module is a tool for conversion between optical and electrical signals, and it is one of the key devices in optical communication. Furthermore, as the demand for the development of optical communication technology increases, the transmission rate of optical modules continues to rise.

### SUMMARY OF THE INVENTION

The present disclosure provides an optical module, including:

an upper shell;

a lower shell, covering the upper shell to form a cavity; and

a circuit board, located in the cavity and including an upper conductive layer, a lower conductive layer, and an intermediate conductive layer located between the upper conductive layer and the lower conductive layer of the circuit board,

where the upper conductive layer is provided with:

a first power supply pin, configured to be connected to a first terminal of a host computer;

a second power supply pin, configured to be connected to a second terminal of the host computer, and having a same voltage as the first power supply pin; and

a dummy pin, located between the first power supply pin and the second power supply pin, where there is a gap between the first power supply pin and the dummy pin; there is a gap between the second power supply pin and the dummy pin;

the intermediate conductive layer is provided with a power supply line; the second power supply pin is connected to the power supply line; and

the dummy pin is connected to the power supply line.

### BRIEF DESCRIPTION OF THE DRAWINGS

To more clearly illustrate the technical solutions in the embodiments of the present disclosure, the accompanying drawings that need to be used in the description of the embodiments or the prior art will be briefly introduced below. Apparently, the accompanying drawings in the description below merely illustrate some embodiments of the present disclosure. Those of ordinary skill in the art may also derive other accompanying drawings from these accompanying drawings without creative efforts.

FIG. 1 is a partial architecture diagram of an optical communication system according to some embodiments of the present disclosure;

FIG. 2 is a partial structural diagram of a host computer according to some embodiments of the present disclosure;

FIG. 3 is a structural diagram of an optical module according to some embodiments of the present disclosure;

FIG. 4 is an exploded view of an optical module according to some embodiments of the present disclosure;

FIG. 5 is a schematic diagram of the position of a gold finger of a circuit board according to some embodiments of the present disclosure;

FIG. 6 is a schematic diagram of connection positions between a gold finger of a circuit board and terminals of a host computer according to some embodiments of the present disclosure;

FIG. 7 is a first schematic partial cross-sectional view of a circuit board according to some embodiments of the present disclosure;

FIG. 8 is a second schematic partial cross-sectional view of a circuit board according to some embodiments of the present disclosure;

FIG. 9 is a schematic diagram of the movement process of a first terminal according to some embodiments of the present disclosure;

FIG. 10 is a schematic diagram of an internal structure of an optical module according to some embodiments of the present disclosure;

FIG. 11 is a schematic diagram of an optical transmitter component and a circuit board according to some embodiments of the present disclosure;

FIG. 12 is a schematic structural diagram of an optical transmitter component according to some embodiments of the present disclosure;

FIG. 13 is a schematic cross-sectional view of an optical transmitter component and a circuit board according to some embodiments of the present disclosure;

FIG. 14 is a first schematic exploded view of an optical transmitter component according to some embodiments of the present disclosure;

FIG. 15 is a first schematic diagram of an optical path of an optical transmitter component according to some embodiments of the present disclosure;

FIG. 16 is a second schematic exploded view of an optical transmitter component according to some embodiments of the present disclosure; and

FIG. 17 is a second schematic diagram of an optical path of an optical transmitter component according to some embodiments of the present disclosure.

### DETAILED DESCRIPTION OF THE EMBODIMENTS

The technical solutions in some embodiments of the present disclosure will be clearly and completely described below with reference to the accompanying drawings. Apparently, the described embodiments are merely some rather than all of the embodiments of the present disclosure. All other embodiments obtained by those of ordinary skill in the art based on the embodiments provided in the present disclosure fall within the scope of protection of the present disclosure.

Unless the context requires otherwise, throughout the description and claims, the term "comprise" and other forms thereof, such as the third-person singular form "comprises" and the present participle form "comprising" are construed in an open, inclusive meaning, that is, "comprising, but not limited to." In the description, the terms "one embodiment," "some embodiments," "exemplary embodiments," "example," "specific example," or "some examples," etc. are intended to indicate that a particular feature, structure, material, or characteristic related to the embodiment or example is included in at least one embodiment or example of the present disclosure. The schematic illustration of the above terms does not necessarily refer to the same embodiment or example. Furthermore, the specific features, structures, materials, or characteristics described may be included in any one or more embodiments or examples in any suitable manner.

Hereinafter, the terms "first" and "second" are for descriptive purposes only, and are not to be understood as indicating or implying relative importance or as implicitly indicating the number of technical features indicated. Thus, features defined with "first" and "second" may explicitly or implicitly include one or more of such features. In the description of the embodiments of the present disclosure, unless otherwise specified, "a plurality of" means two or more.

In describing some embodiments, the expressions "coupled" and "connected" and extensions thereof may be used. For example, in describing some embodiments, the term "connected" may be used to indicate that two or more components are in direct physical contact or electrical contact with each other. For another example, in describing some embodiments, the term "coupled" may be used to indicate that two or more components are in direct physical contact or electrical contact with each other. However, the term "coupled" or "communicatively coupled" may also indicate that two or more components are not in direct contact with each other, but still cooperate or interact with each other. The embodiments disclosed herein are not necessarily limited to the contents herein.

"At least one of A, B, and C" has the same meaning as "at least one of A, B, or C," encompassing the following combinations of A, B, and C: only A, only B, only C, a combination of A and B, a combination of A and C, a combination of B and C, and a combination of A, B, and C.

"A and/or B" includes three combinations of only A, only B, and a combination of A and B.

The use of "suitable for" or "configured to" herein means open and inclusive language that does not exclude devices suitable for or configured to perform additional tasks or steps.

As used herein, "about," "approximately," or "approximately" includes a stated value as well as an average within an acceptable range of deviation from a particular value, where the acceptable range of deviation is determined by one of ordinary skill in the art taking into account the measurement in question and the error associated with the measurement of a particular amount (i.e., limitations of the measurement system).

In optical communication technology, in order to establish information transmission between information processing devices, it is necessary to load information onto light and use the propagation of light to achieve the transmission of information. The light loaded with information is an optical signal. When the optical signal propagates in information transmission devices, the loss of optical power can be reduced, such that high-speed, long-distance, and low-cost information transmission can be achieved. The information that can be processed by the information processing devices exists in the form of electrical signals. Optical network units/gateways, routers, switches, mobile phones, computers, servers, tablet computers, and televisions are common information processing devices, while optical fibers and optical waveguides are common information transmission devices.

Optical modules enable the conversion between optical signals and electrical signals from the information processing devices and the information transmission devices. For example, an optical signal input or an optical signal output of an optical module is connected to an optical fiber, and an electrical signal input or an electrical signal output of the optical module is connected to an optical network unit; a first optical signal from the optical fiber is transmitted to the optical module, and the optical module converts the first optical signal into a first electrical signal and transmits the first electrical signal to the optical network unit; and a second electrical signal from the optical network unit is transmitted to the optical module, and the optical module converts the second electrical signal into a second optical signal and transmits the second optical signal to the optical fiber. Since the information processing devices can be interconnected via an electrical signal network, at least one type of information processing device needs to be directly connected to the optical module, and not all types of information processing devices need to be directly connected to the optical module. The information processing device directly connected to the optical module is referred to as a host computer of the optical module.

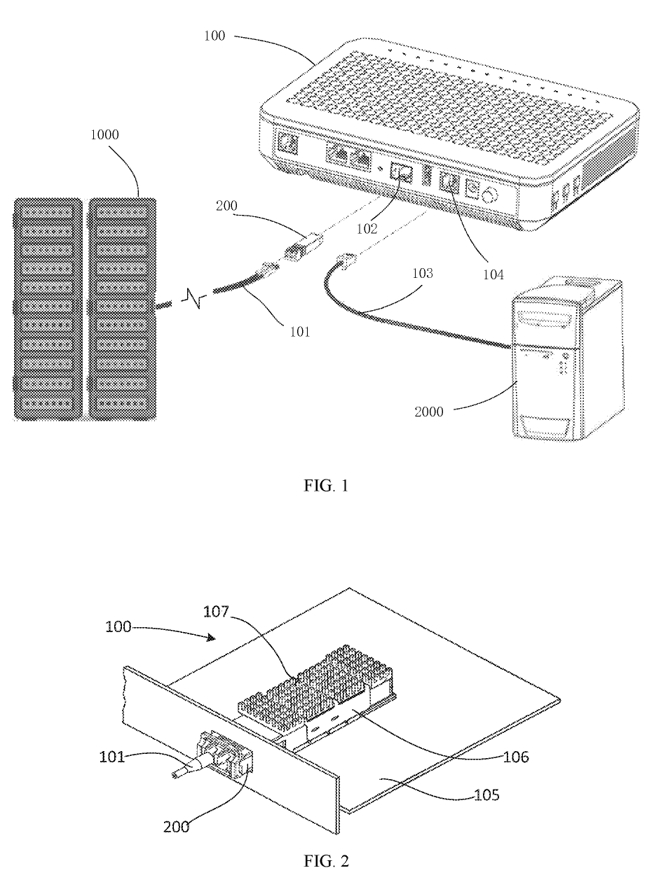

FIG. 1 is a partial architecture diagram of an optical communication system according to some embodiments of the present disclosure. As shown in FIG. 1, the optical communication system locally includes a remote information processing device 1000, a local information processing device 2000, a host computer 100, an optical module 200, an optical fiber 101, and a network cable 103.

One end of the optical fiber 101 extends toward the remote information processing device 1000, and the other end thereof is connected to an optical interface of the optical module 200. An optical signal can undergo total reflection in the optical fiber 101. The propagation of the optical signal in the total reflection direction enables it to nearly maintain original optical power. The optical signal undergoes multiple total reflections in the optical fiber 101 to transmit an optical signal from the remote information processing device 1000 to the optical module 200 or to propagate light from the optical module 200 to the remote information processing device 1000, thereby achieving long-distance and low-power-loss information transmission.

The number of optical fibers 101 may be one or more (two or more). The optical fiber 101 and the optical module 200 may be movably connected in a pluggable manner or fixedly connected.

The host computer 100 is provided with an optical module interface 102. The optical module interface 102 is configured to be connected to the optical module 200, thereby establishing a unidirectional/bidirectional electrical signal connection between the host computer 100 and the optical module 200. The host computer 100 is configured to provide a data signal to the optical module 200, receive a data signal from the optical module 200, or monitor and control a working state of the optical module 200.

The host computer 100 is provided with an external electrical interface, such as a universal serial bus (USB) interface or a network cable interface 104. The external electrical interface can be connected to the electrical signal network. For example, the network cable interface 104 is configured to be connected to the network cable 103, thereby establishing a unidirectional/bidirectional electrical signal connection between the host computer 100 and the network cable 103.

Optical network units (ONUs), optical line terminals (OLTs), optical network terminals (ONTs), and data center servers are common host computers.

One end of the network cable 103 is connected to the local information processing device 2000, and the other end thereof is connected to the host computer 100, thereby establishing an electrical signal connection between the local information processing device 2000 and the host computer 100 via the network cable 103.

For example, a third electrical signal sent by the local information processing device 2000 is transmitted to the host computer 100 via the network cable 103. The host computer 100 generates a second electrical signal based on the third electrical signal. The second electrical signal from the host computer 100 is transmitted to the optical module 200. The optical module 200 converts the second electrical signal into a second optical signal and transmits the second optical signal to the optical fiber 101. The second optical signal is transmitted through the optical fiber 101 to the remote information processing device 1000.

For example, a first optical signal from the remote information processing device 1000 is propagated through the optical fiber 101. The first optical signal from the optical fiber 101 is transmitted to the optical module 200. The optical module 200 converts the first optical signal into a first electrical signal and transmits the first electrical signal to the host computer 100. The host computer 100 generates a fourth electrical signal based on the first electrical signal and transmits the fourth electrical signal to the local information processing device 2000.

The optical module is a tool to implement the conversion between optical signals and electrical signals. During the conversion between the optical signals and the electrical signals, the information remains unchanged, and the encoding and decoding methods for the information may vary.

FIG. 2 is a partial structural diagram of a host computer according to some embodiments of the present disclosure. To clearly show the connection relationship between the optical module 200 and the host computer 100, FIG. 2 shows only the structure of the host computer 100 related to the optical module 200. As shown in FIG. 2, the host computer 100 further includes a printed circuit board (PCB) 105 disposed in a housing, a cage 106 disposed on a surface of the PCB 105, a heat sink 107 disposed on the cage 106, and an electrical connector disposed inside the cage 106 (not shown in the figure). The heat sink 107 has a protruding structure to increase the heat dissipation area. A fin-shaped structure is a common protruding structure.

The optical module 200 is inserted into the cage 106 of the host computer 100, and the optical module 200 is fixed by the cage 106. The heat generated by the optical module 200 is conducted to the cage 106 and then diffused through the heat sink 107. After the optical module 200 is inserted into the cage 106, the electrical interface of the optical module 200 is connected to the electrical connector inside the cage 106.

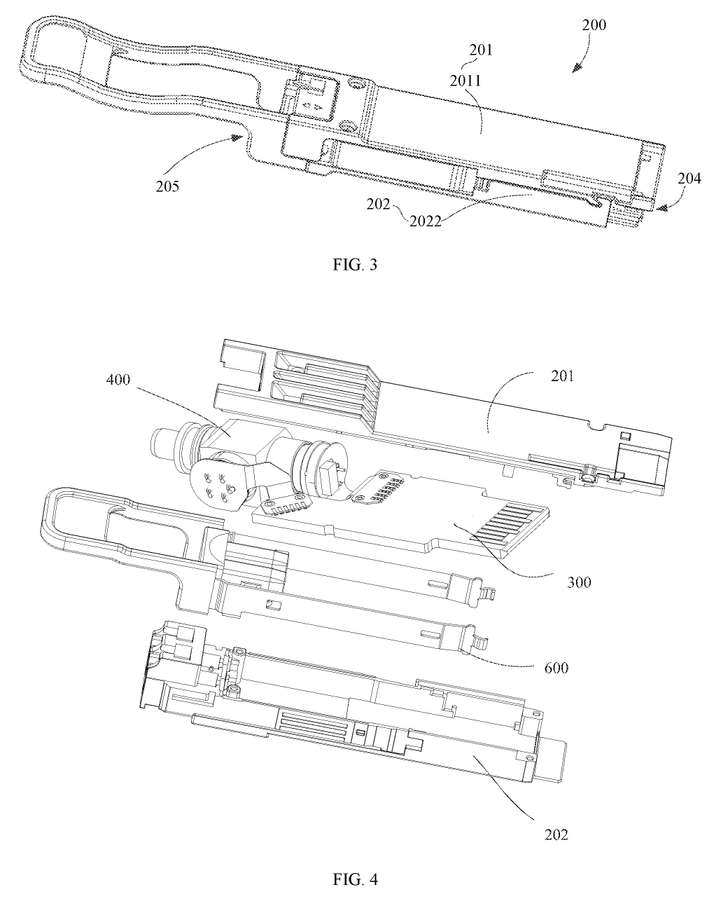

FIG. 3 is a structural diagram of an optical module according to some embodiments of the present disclosure, and FIG. 4 is an exploded view of an optical module according to some embodiments of the present disclosure. As shown in FIG. 3 and FIG. 4, the optical module 200 includes a shell, and a circuit board 300, an optical transmitter component 400 and an optical receiver component 500 disposed in the shell. However, the present disclosure is not limited to this. In some embodiments, the optical module 200 includes either an optical transmitter component 400 or an optical receiver component 500.

The shell includes an upper shell 201 and a lower shell 202. The upper shell 201 covers the lower shell 202 to form the shell with an opening 204 and an opening 205. The outer contour of the shell is generally square.

In some embodiments, the lower shell 202 includes a bottom plate and two lower side plates 2022 located on two sides of the bottom plate and perpendicular to the bottom plate; and the upper shell 201 includes a cover plate 2011. The cover plate 2011 covers the two lower side plates 2022 of the lower shell 202 to form the shell.

In some embodiments, the lower shell 202 includes a bottom plate and two lower side plates 2022 located on two sides of the bottom plate and perpendicular to the bottom plate; and the upper shell 201 includes a cover plate 2011 and two upper side plates located on two sides of the cover plate 2011 and perpendicular to the cover plate 2011. The two upper side plates and the two lower side plates 2022 are combined to ensure that the upper shell 201 covers the lower shell 202.

The direction of a line connecting the opening 204 to the opening 205 may be consistent or inconsistent with the length direction of the optical module 200. For example, the opening 204 is located at an end of the optical module 200 (the right end in FIG. 3), and the opening 205 is also located at an end of the optical module 200 (the left end in FIG. 3). Alternatively, the opening 204 is located at an end of the optical module 200, and the opening 205 is located on a side of the optical module 200. The opening 204 is an electrical interface. A gold finger of the circuit board 300 extends from the electrical interface and is inserted into the electrical connector of the host computer. The opening 205 is an optical port configured to be connected to the optical fiber 101, such that the optical fiber 101 is connected to the optical transmitter component 400 and/or the optical receiver component 500 in the optical module 200.

An assembly method for combining the upper shell 201 with the lower shell 202 is adopted, such that the circuit board 300, the optical transmitter component 400, the optical receiver component 500, and other components can be conveniently mounted in the shell. These components can be encapsulated and protected by the upper shell 201 and lower shell 202. In addition, when the circuit board 300, the optical transmitter component 400, the optical receiver component 500, and other components are assembled, the deployment of positioning components, heat dissipation components, and electromagnetic shielding components of these components is facilitated, which is conducive to automated production.

In some embodiments, the upper shell 201 and the lower shell 202 are made of metal, which is conducive to electromagnetic shielding and heat dissipation.

In some embodiments, the optical module 200 further includes an unlocking component 600 located outside its shell. The unlocking component 600 is configured to establish a fixed connection between the optical module 200 and the host computer, or to release the fixed connection between the optical module 200 and the host computer.

For example, the unlocking component 600 is located outside the two lower side plates 2022 of the lower shell 202, and includes an engaging component that matches the cage 106 of the host computer. When the optical module 200 is inserted into the cage 106, the optical module 200 is fixed in the cage 106 by the engaging component of the unlocking component 600. When the unlocking component 600 is pulled, the engaging component of the unlocking component 600 moves accordingly, such that the connection between the engaging component and the host computer is changed to release the fixed connection between the optical module 200 and the host computer, thereby allowing the optical module 200 to be withdrawn from the cage 106.

The circuit board 300 includes circuit traces, electronic components, and chips, where the electronic components and the chips are connected together through the circuit traces according to the circuit design to implement the functions such as power supply, electrical signal transmission, and grounding. The electronic components may include, for example, capacitors, resistors, transistors, and metal-oxide-semiconductor field-effect transistors (MOSFETs). The chips may include, for example, microcontroller units (MCUs), laser driving chips, transimpedance amplifiers (TIAs), limiting amplifiers, clock and data recovery (CDR) chips, power management chips, and digital signal processing (DSP) chips.

The circuit board 300 is generally a rigid circuit board. The rigid circuit board can also serve a load-bearing function because of its relatively rigid material, for example, the rigid circuit board can stably carry the above-mentioned electronic components and chips. The rigid circuit board can also be inserted into the electrical connector in the cage of the host computer.

The circuit board 300 further includes a gold finger formed on an end surface thereof. The gold finger is composed of a plurality of independent pins. The circuit board 300 is inserted into the cage 106 and is connected to the electrical connector in the cage 106 via the gold finger. The gold finger may be disposed on only one surface of the circuit board 300 (e.g., the upper surface shown in FIG. 4), or may be disposed on the upper and lower surfaces of the circuit board 300 to provide more pins. The gold finger is configured to establish an electrical connection with the host computer to achieve power supply, grounding, inter-integrated circuit (I2C) signal transmission, data signal transmission, etc.

Certainly, flexible circuit boards may also be used in some optical modules. The flexible circuit boards are generally used in conjunction with rigid circuit boards as a supplement to the rigid circuit boards.

The gold finger receives an electrical signal from the host computer and then transmits the electrical signal to the optical transmitter component via a signal line in the circuit board, and the optical transmitter component converts the electrical signal into an optical signal. The gold finger is provided with various pins having different functions, such as ground pins and power supply pins.

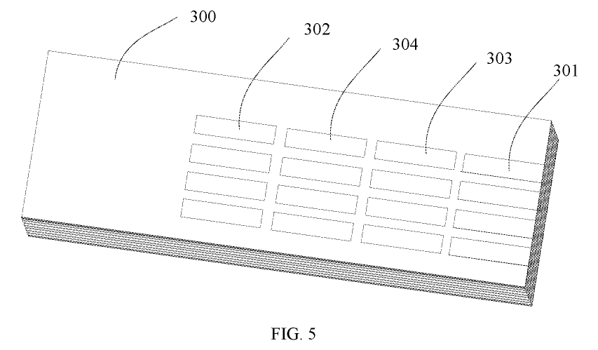

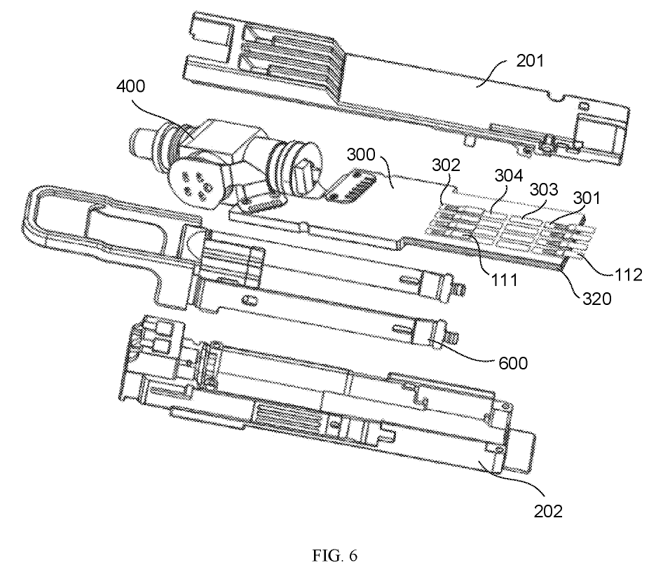

FIG. 5 is a schematic diagram of the position of a gold finger of a circuit board according to some embodiments of the present disclosure. FIG. 6 is a schematic diagram of connection positions between a gold finger of a circuit board and terminals of a host computer according to some embodiments of the present disclosure. As shown in FIG. 5 and FIG. 6, in some examples of the present disclosure, two groups of pins with the same function are provided. For example, the power supply pins include a first power supply pin 302 and a second power supply pin 301; and the ground pins include a first ground pin and a second ground pin. The first power supply pin 302 and the second power supply pin 301 have the same function. In the example, both the first power supply pin 302 and the second power supply pin 301 provide a voltage of 3.3 V. A first dummy pin 303 and a second dummy pin 304 are disposed between the first power supply pin 302 and the second power supply pin 301. The second power supply pin 301, the first dummy pin 303, the second dummy pin 304, and the first power supply pin 302 are sequentially arranged and not in communication with one another.

It should be noted that the number of first dummy pins may be set based on the actual size of terminals of the host computer (including a distance between a first terminal and a second terminal) and an effective contact surface between the first terminal and the circuit board. Two dummy pins (the first dummy pin and the second dummy pin) or three or more dummy pins may be disposed between the first power supply pin 302 and the second power supply pin 301, and there is a gap between every two adjacent dummy pins.

The host computer is provided with a first terminal 111 and a second terminal 112, where the first terminal 111 is in contact connection with the first power supply pin 302, and the second terminal 112 is in contact connection with the second power supply pin 301. During power-on insertion of the optical module, the first terminal 111 first passes through the second power supply pin 301, then sequentially passes through the first dummy pin 303 and the second dummy pin 304, and finally reaches the first power supply pin 302. During power-on of the module, the terminal of the host computer is connected to a power supply line via the power supply pin, and the power supply line is connected to a soft-start circuit. The soft-start circuit enables debounce and delayed power-on, and can control the rising slope and amplitude of an input current. Accordingly, the optical module needs to undergo a process of power-on, power-off, followed by power-on. Rapid insertion will cause the module to undergo rapid secondary power-on. In this case, the soft-start circuit of the module is still in a conducting state, resulting in failure of a soft-start function, triggering an inrush current, and affecting the performance of the optical module.

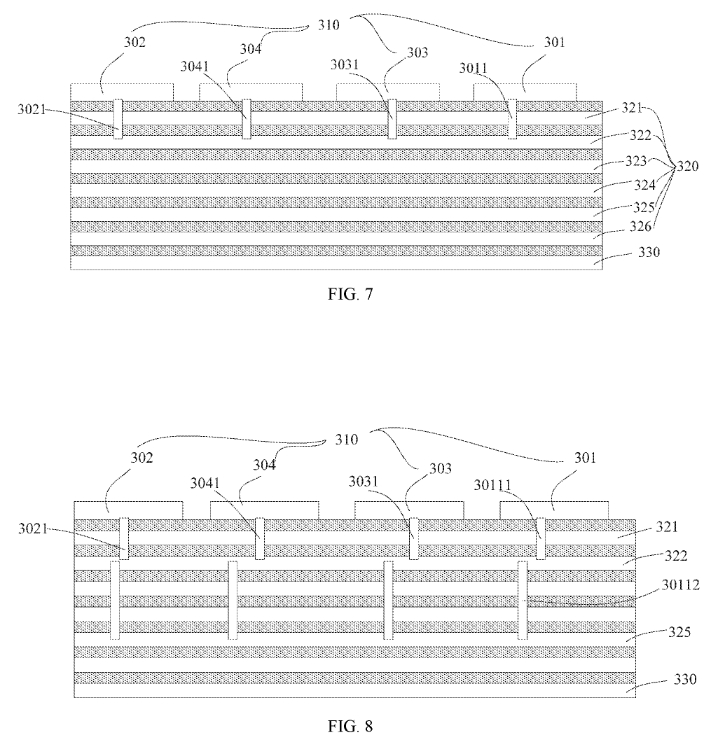

FIG. 7 is a first schematic partial cross-sectional view of a circuit board according to some embodiments of the present disclosure. As shown in FIG. 7, the circuit board includes an upper conductive layer 310, a lower conductive layer 330, and an intermediate conductive layer 320 located between the upper conductive layer and the lower conductive layer.

In one example, the intermediate conductive layer includes at least a first intermediate layer 321. An insulating layer is disposed between adjacent conductive layers to isolate electrical conduction therebetween.

By way of example, the intermediate conductive layer 320 includes a first intermediate layer 321, a second intermediate layer 322, a third intermediate layer 323, a fourth intermediate layer 324, a fifth intermediate layer 325, and a sixth intermediate layer 326.

The power supply line is located in the intermediate conductive layer. By way of example, the power supply line may be located in the second intermediate layer 322, and may also be located in the third intermediate layer 323 or other intermediate regions.

To prevent secondary power-on of the optical module during power-on, the present disclosure provides an optical module, in which a first through hole 3031 is formed below the first dummy pin 303, and the first through hole 3031 has one end connected to the first dummy pin 303 and the other end connected to the power supply line.

In one example, a third through hole 3011 is formed below the second power supply pin 301, and the third through hole 3011 has one end connected to the second power supply pin 301 and the other end connected to the power supply line.

In one example, a second through hole 3041 is formed below the second dummy pin 304, and the second through hole 3041 has one end connected to the second dummy pin 304 and the other end connected to the power supply line.

In one example, a fourth through hole 3021 is formed below the first power supply pin 302, and the fourth through hole 3021 has one end connected to the first power supply pin 302 and the other end connected to the power supply line.

Based on the above arrangement, the second power supply pin 301 is connected to the first dummy pin 303 via the third through hole 3011, the power supply line, and the first through hole 3031, such that during movement from the second power supply pin 301 to the first dummy pin 303, the first terminal 111 remains electrically connected to the second power supply pin 301, thereby preventing secondary power-on. The power supply line is further connected to the power management chip.

Similarly, the second power supply pin 301 is connected to the second dummy pin 304 via the third through hole, the power supply line, and the second through hole, such that during movement from the first dummy pin 303 to the second dummy pin 304, the first terminal remains electrically connected to the second power supply pin 301, thereby preventing secondary power-on.

In some embodiments, a fourth through hole 3021 is formed below the first power supply pin 302, and the fourth through hole 3021 has one end connected to the first power supply pin 302 and the other end connected to the power supply line. The first power supply pin 302, the second power supply pin 301, the first dummy pin 303, and the second dummy pin 304 are electrically connected, such that during power-on of the optical module (i.e., movement of the first terminal from the second power supply pin to the first power supply pin), or during power-off of the optical module (i.e., movement of the first terminal from the first power supply pin to the second power supply pin), the first terminal is always electrically connected to the power supply line, thereby preventing power-off followed by power-on during power-on or power-off, and improving the stability of the optical module.

FIG. 8 is a second schematic partial cross-sectional view of a circuit board according to some embodiments of the present disclosure. As shown in FIG. 8, in some embodiments, the power supply line is located in the fifth intermediate layer 325, and the first through hole 3031 includes a first sub-hole and a second sub-hole to establish an electrical connection between the first dummy pin and the power supply line. A first connecting line is disposed between the first sub-hole and the second sub-hole, and the first sub-hole and the second sub-hole are not aligned in the vertical direction. One end of the first sub-hole is connected to the first dummy pin, and one end of the second sub-hole is connected to the power supply line.

The first sub-hole penetrates through the first intermediate layer and reaches the second intermediate layer, the second sub-hole starts from the second intermediate layer (in communication with the second intermediate layer), penetrates through the third intermediate layer and the fourth intermediate layer, and reaches the fifth intermediate layer, and the first connecting line is located in the second intermediate layer and used for connecting the first sub-hole to the second sub-hole.

In one example, the second through hole 3041 includes a third sub-hole and a fourth sub-hole to establish an electrical connection between the second dummy pin and the power supply line. A second connecting line is disposed between the third sub-hole and the fourth sub-hole, and the third sub-hole and the fourth sub-hole are not aligned in the vertical direction.

The third sub-hole penetrates through the first intermediate layer and reaches the second intermediate layer, the fourth sub-hole starts from the second intermediate layer (in communication with the second intermediate layer), penetrates through the third intermediate layer and the fourth intermediate layer, and reaches the fifth intermediate layer, and the second connecting line is located in the second intermediate layer and used for connecting the third sub-hole to the fourth sub-hole.

In one example, the third through hole 3011 includes a fifth sub-hole 30111 and a sixth sub-hole 30112 to establish an electrical connection between the second power supply pin and the power supply line. A third connecting line is disposed between the fifth sub-hole 30111 and the sixth sub-hole 30112, and the fifth sub-hole 30111 and the sixth sub-hole 30112 are not aligned in the vertical direction.

The fifth sub-hole 30111 penetrates through the first intermediate layer and reaches the second intermediate layer, the sixth sub-hole 30112 starts from the second intermediate layer (in communication with the second intermediate layer), penetrates through the third intermediate layer and the fourth intermediate layer, and reaches the fifth intermediate layer, and the third connecting line is located in the second intermediate layer and used for connecting the fifth sub-hole 30111 to the sixth sub-hole 30112.

In one example, the fourth through hole 3021 includes a seventh sub-hole and an eighth sub-hole to establish an electrical connection between the first power supply pin and the power supply line. A fourth connecting line is disposed between the seventh sub-hole and the eighth sub-hole, and the seventh sub-hole and the eighth sub-hole are not aligned in the vertical direction.

The seventh sub-hole penetrates through the first intermediate layer and reaches the second intermediate layer, the eighth sub-hole starts from the second intermediate layer (in communication with the second intermediate layer), penetrates through the third intermediate layer and the fourth intermediate layer, and reaches the fifth intermediate layer, and the fourth connecting line is located in the second intermediate layer and used for connecting the seventh sub-hole to the eighth sub-hole.

It should be noted that the number of sub-holes in the above first through hole, second through hole, third through hole, and fourth through hole is not limited, and may be set according to the actual thickness of the circuit board and the number of layers where the power supply lines are disposed. For example, there may be three sub-holes, and the three sub-holes are not aligned in the vertical direction.

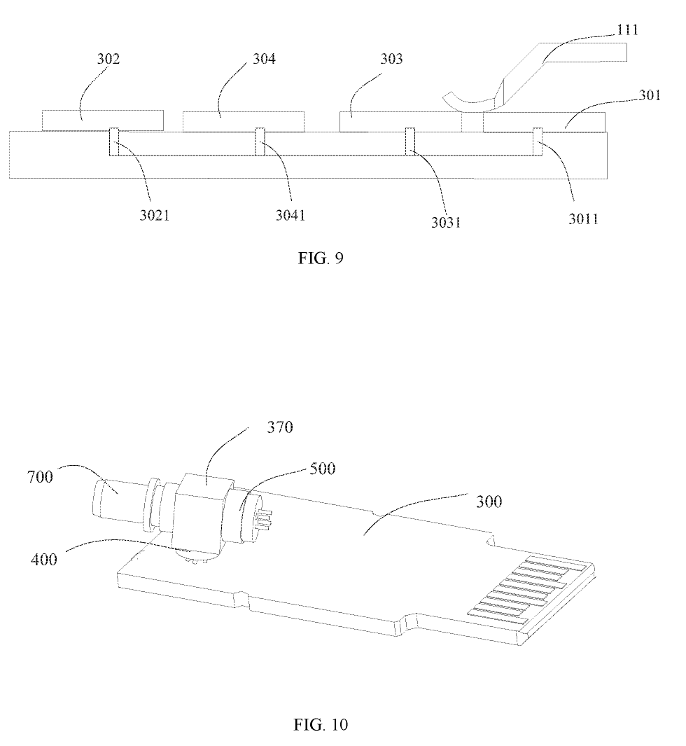

FIG. 9 is a schematic diagram of the movement process of a first terminal according to some embodiments of the present disclosure. As shown in FIG. 9, the contact surface between the terminal and the gold finger is defined as an energized surface. To prevent power interruption caused by a gap between the second power supply pin 301 and the first dummy pin 303 during movement of the first terminal from the second power supply pin 301 to the first dummy pin 303, the area of the energized surface of the first terminal is greater than the area of the gap between the second power supply pin 301 and the first dummy pin 303, or the energized surface of the first terminal can cover the gap between the second power supply pin 301 and the first dummy pin 303, such that during movement of the first terminal 111 from the second power supply pin 301 to the first dummy pin 303, the first terminal 111 always remains in contact with at least one of the second power supply pin 301 or the first dummy pin 303, that is, the first terminal 111 always remains electrically connected to the power supply line.

In some embodiments, the distance of the gap between the second power supply pin and the first dummy pin is less than the distance at the connection (contact) portion between the terminal of the host computer and the circuit board.

Similarly, to prevent power interruption caused by a gap between the first dummy pin 303 and the second dummy pin 304 during movement of the first terminal 111 from the first dummy pin 303 to the second dummy pin 304, the area of the energized surface of the first terminal 111 is greater than the area of the gap between the first dummy pin 303 and the second dummy pin 304, or the energized surface of the first terminal 111 can cover the gap between the first dummy pin 303 and the second dummy pin 304, such that during movement of the first terminal 111 from the first dummy pin 303 to the second dummy pin 304, the first terminal always remains in contact with at least one of the second dummy pin 304 or the first dummy pin 303, that is, the first terminal 111 always remains electrically connected to the power supply line.

Similarly, to prevent power interruption caused by a gap between the first power supply pin 302 and the second dummy pin 304 during movement of the first terminal 111 from the second dummy pin 304 to the first power supply pin 302, the area of the energized surface of the first terminal 111 is greater than the area of the gap between the first power supply pin 302 and the second dummy pin 304, or the energized surface of the first terminal 111 can cover the gap between the first power supply pin 302 and the second dummy pin 304, such that during movement of the first terminal 111 from the second dummy pin 304 to the first power supply pin 302, the first terminal always remains in contact with at least one of the second dummy pin 304 or the first power supply pin 302, that is, the first terminal 111 always remains electrically connected to the power supply line.

The present disclosure provides an optical module, in which a first through hole 3031 is formed below the first dummy pin 303, and the first through hole 3031 has one end connected to the first dummy pin 303 and the other end connected to the power supply line. A fourth through hole 3021 is formed below the first power supply pin 302, and the fourth through hole 3021 has one end connected to the first power supply pin 302 and the other end connected to the power supply line. A second through hole 3041 is formed below the second dummy pin 304, and the second through hole 3041 has one end connected to the second dummy pin 304 and the other end connected to the power supply line. A third through hole 3011 is formed below the second power supply pin 301, and the third through hole 3011 has one end connected to the second power supply pin 301 and the other end connected to the power supply line. The second power supply pin 301 is connected to the first dummy pin 303 via the third through hole 3011, the power supply line, and the first through hole 3031, such that during movement of the first terminal 111 from the second power supply pin 301 to the first power supply pin 302, the first terminal 111 always remains in contact with at least one of the first power supply pin 302, the second dummy pin 304, the first dummy pin 303, or the second power supply pin 301, that is, the first terminal 111 always remains electrically connected to the power supply line, thereby preventing secondary power-on from affecting the performance of the optical module.

The optical transmitter component 400 and/or the optical receiver component 500 is also referred to as an optical transceiver component.

The optical transmitter component 400 and/or the optical receiver component 500 is located on one side of the circuit board 300 away from the gold finger. In some embodiments, the optical transmitter component 400 and the optical receiver component 500 are respectively physically separated from the circuit board 300 and are respectively electrically connected to the circuit board 300 via corresponding flexible circuit boards or electrical connectors.

In some embodiments, the optical transmitter component and/or the optical receiver component may be directly disposed on the circuit board 300, and may be disposed on a surface or a side of the circuit board.

The optical transmitter component 400 is electrically connected to the circuit board 300, thereby establishing electrical connections between electrical devices in the optical transmitter component 400 and the circuit board 300.

In some embodiments, the power supply line is connected to the soft-start circuit, and the soft-start circuit is electrically connected to the optical transmitter component 400, thereby establishing an electrical connection between the optical transmitter component 400 and the power supply pin.

FIG. 10 is a schematic diagram of an internal structure of an optical module according to some embodiments of the present disclosure. As shown in FIG. 10, in the optical module according to this embodiment, the optical module 200 further includes a round-square tube body 370. The optical transmitter component 400 and the optical receiver component 500 are embedded in the round-square tube body 370. The optical transmitter component 400 and the optical receiver component 500 are respectively electrically connected to the circuit board 300, such that the optical transmitter component 400 is used for outputting signal light and the optical receiver component 500 is used for receiving signal light from outside the optical module, thereby achieving electro-optical and opto-electrical conversion of the optical module. A lens assembly is usually disposed in the round-square tube body 370, and the lens assembly is configured to change the propagation direction of the signal light output by the optical transmitter component 400 or the signal light input from an external optical fiber.

In some embodiments, the optical transmitter component 400 and the optical receiver component 500 are electrically connected to the circuit board 300 via flexible circuit boards, such that the electrical devices in the optical transmitter component 400 and the optical receiver component 500 are electrically connected to the circuit board 300 via the corresponding flexible circuit boards.

In some embodiments, the round-square tube body 370 is located above the circuit board 300. The optical transmitter component 400 adopts a coaxial transistor outline (TO) package structure. The pins of the optical transmitter component 400 face the circuit board 300, and the pins pass through the through holes in the circuit board 300. Soldering is performed from the lower surface of the circuit board between the pins and the circuit board.

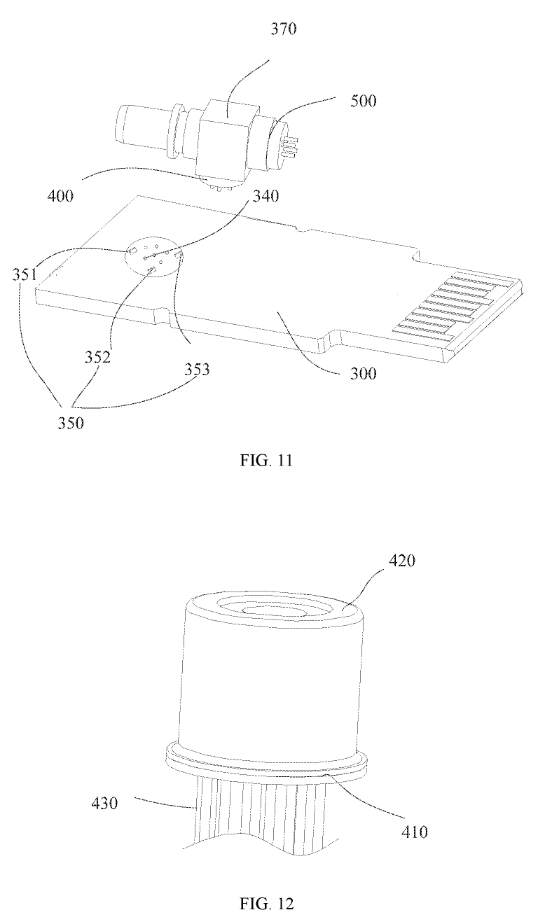

FIG. 11 is a schematic diagram of an optical transmitter component and a circuit board according to some embodiments of the present disclosure, and FIG. 12 is a schematic structural diagram of an optical transmitter component according to some embodiments of the present disclosure. As shown in FIG. 11 and FIG. 12, the optical transmitter component according to this embodiment includes a header 410, a cap 420, and other devices disposed in the header 410 and the cap 420. The cap 420 covers one end of the header 410. The header 410 includes several pins 430. The pins are configured to establish electrical connections between the circuit board and the other electrical devices in the optical transmitter component 400, such that the other electrical devices in the optical transmitter component 400 are ultimately connected to the power supply pin via the power supply line. In this embodiment, the structure shown in FIG. 12 is used as an example for description.

The cap is fastened over the header 410 to form a light-emitting space. An optical transmitter chip and a thermoelectric cooler are disposed inside the light-emitting space. The header 410 is configured to support and carry the optical transmitter chip and the thermoelectric cooler. The header 410 is provided with a plurality of through holes for fixing the pins 430.

The circuit board is provided with a plurality of pin through holes 340. After passing through the pin through hole, one end of the pin 430 is exposed on the other side (the lower surface) of the circuit board. Solder enters the pin through hole from the other side (the lower surface) of the circuit board to establish an electrical connection between the pin 430 and the pin through hole.

However, there is excess solder extending from one pin to another along the surface of the circuit board or the header, resulting in poor power supply.

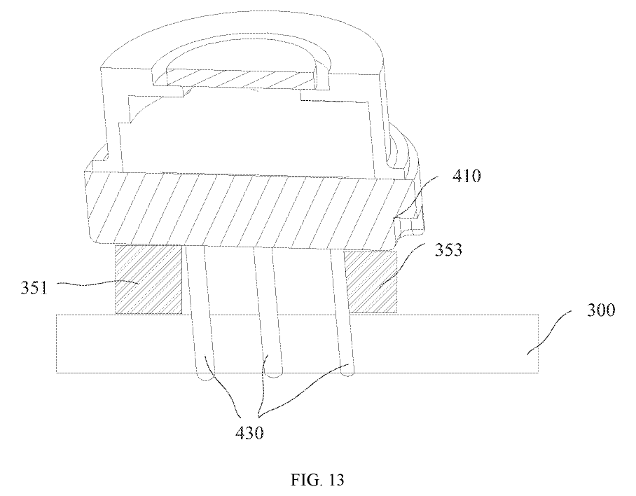

FIG. 13 is a schematic cross-sectional view of an optical transmitter component and a circuit board according to some embodiments of the present disclosure. As shown in FIG. 11 and FIG. 13, the circuit board is provided with a plurality of pin through holes 340. After passing through the pin through hole, one end of the pin 430 is exposed on the other side (the lower surface) of the circuit board. The optical transmitter component is located on the upper surface of the circuit board, and a lifting component 350 is disposed between the header 410 and the upper surface of the circuit board. The lifting component 350 is located on an edge of the pin through hole. The upper surface of the lifting component 350 is connected to the header 410, and the lower surface of the lifting component 350 is connected to the circuit board.

The lifting component 350 enables a gap to be formed between the header 410 and the upper surface of the circuit board, such that after the solder fills a gap between the pin through hole 340 and the pin 430, excess solder continues to extend along the pin first, thereby preventing the solder from extending from one pin to another along the surface of the circuit board or the header, and improving the soldering yield. The space between adjacent pins is increased, thereby preventing solder bridging therebetween, and improving the soldering yield.

By way of example, the lifting component 350 may be an insulating block, and the insulating block may be connected to the circuit board via insulating adhesive.

In some embodiments, the lifting component may include a plurality of electronic components, and the lower surfaces of the electronic components may be soldered to the circuit board.

In some embodiments, the electronic component may include one or more of a resistor, an inductor, or a capacitor. The number of electronic components may be 2 (sets), 3 (sets), 4 (sets), or other values, and can be set according to the size of the header and the size of the electronic components. By way of example, the lifting component 350 includes a first resistor 351, a second resistor 352, and a third resistor 353. The first resistor 351, the second resistor 352, and the third resistor 353 are uniformly distributed below the header 410. For ease of installation, the first resistor, the second resistor, and the third resistor are located outside the pins 430, and the projection of the header 410 on the circuit board covers the first resistor, the second resistor, and the third resistor. The first resistor 351, the second resistor 352, and the third resistor 353 are spaced apart in a triangular pattern, which can be understood as the first resistor 351, the second resistor 352, and the third resistor 353 being uniformly distributed around the central axis of the header 410.

In some embodiments, the upper surface of the circuit board is provided with a first pad, a second pad, and a third pad, and the projection of the header 410 on the circuit board covers the first pad, the second pad, and the third pad. The first pad is connected to the first resistor, the second pad is connected to the second resistor, and the third pad is connected to the third resistor.

In some embodiments, the center of the first resistor is located within the projection of the header 410 on the circuit board. The center of the second resistor is located within the projection of the header 410 on the circuit board, and the center of the third resistor is located within the projection of the header 410 on the circuit board.

In some embodiments, the lifting component is not in contact with the pins, thereby preventing the solder from extending along the pins to the lifting component.

According to the present disclosure, adding three 0201 package resistors on the circuit board and under the header will raise the entire header, increase the spacing between the header and the circuit board, and prevent the solder from extending along the pins to the header, thereby improving the soldering yield. Three points form a plane, which also enhance the stability and reliability of soldering. The optical module according to the present disclosure is beneficial to improving the reliability of the circuit board and increasing the product yield.

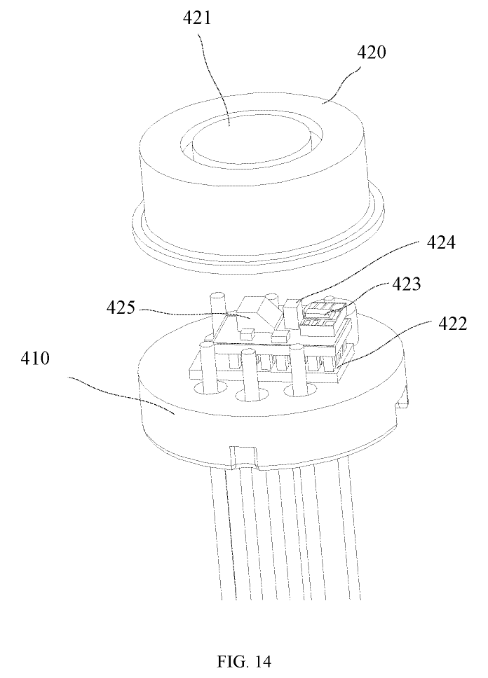

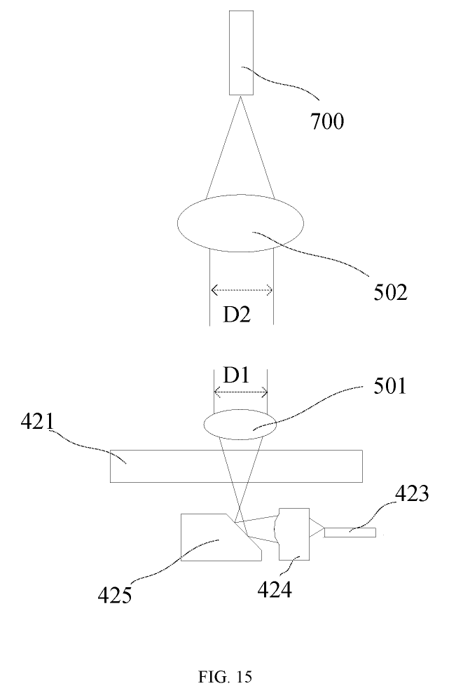

FIG. 14 is a first schematic exploded view of an optical transmitter component according to some embodiments of the present disclosure. FIG. 15 is a first schematic diagram of an optical path of an optical transmitter component according to some embodiments of the present disclosure. As shown in FIG. 14 and FIG. 15, the optical transmitter component 400 includes a header 410, a cap 420, and other devices disposed in the header 410 and the cap 420. The cap 420 covers one end of the header 410. The header 410 includes several pins 430. The pins are configured to establish electrical connections between the circuit board and other electrical devices in the optical transmitter component 400.

The optical transmitter component adopts a coaxial TO package, and includes a header and a cap covering the header. Optoelectronic devices such as an optical transmitter chip and a photodiode are placed on a surface of the header. The cap is provided with an optical window for light transmission. The header and the cap encapsulate the optical transmitter chip, the photodiode, and other optoelectronic devices in a sealed cavity.

The header is provided with a plurality of pins. The pins pass through the header and protrude from the surface of the header, and the pins are wrapped with glass to achieve insulation between the pins and the header. The optoelectronic devices are sealed between the header and the cap, and are electrically connected to the outside via the pins passing through the header.

The thermoelectric cooler 422 is generally bonded to the header with silver adhesive, to dissipate heat from the optoelectronic devices such as the optical transmitter chip 423. That is, the optical transmitter chip, the photodiode, and other optoelectronic devices are disposed on the thermoelectric cooler, and the heat generated by the optical transmitter chip, the photodiode, and other optoelectronic devices is transferred to the thermoelectric cooler for heat dissipation.

In some embodiments, the optical transmitter component further includes a first converging lens 424 and a reflecting mirror 425. The first converging lens 424 is located in an output optical path of the optical transmitter chip 423 and converges divergent light emitted by the optical transmitter chip 423. The first converging lens 424 is located between the optical transmitter chip 423 and the reflecting mirror 425. The reflecting mirror 425 reflects the converged light. The reflected light is directed toward the optical window 421 and enters the round-square tube body 370 after passing through the optical window.

A substrate is disposed above the thermoelectric cooler 422. The optical transmitter chip, the first converging lens 424, and the reflecting mirror 425 are all disposed above the substrate.

A collimating lens 501 and a second converging lens 502 are disposed in the round-square tube body. The collimating lens 501 is configured to convert light emitted from the optical window into a collimated beam. The second converging lens 502 is located between the collimating lens 501 and an optical fiber 700, and converts a parallel beam into converged light to enter the optical fiber 700.

In some embodiments, the light output direction of the optical transmitter chip 423 is parallel to the optical window 421. After being reflected by the reflecting mirror 425, light is directed toward the optical window.

The light reflected by the reflecting mirror 425 continues to diverge after passing through a focal point, where the focal point is located between the optical window and the reflecting mirror 425. In the packaged optical transmitter component 400, the position of the focal point is fixed. By adjusting the distance between the collimating lens 501 and the reflecting mirror 425, the diameter D2 of the beam collimated by the collimating lens 501 can match the collimation diameter D1 of the second converging lens 502.

The diameter D2 of the beam collimated by the collimating lens 501 matches the collimation diameter D1 of the second converging lens 502, which can be understood as making D2 as equal to D1 as possible, or ensuring that the ratio of the difference between D2 and D1 to D1 is less than 5%.

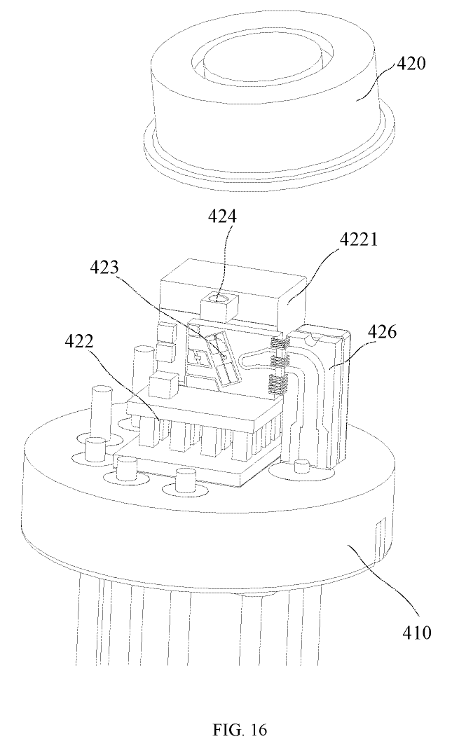

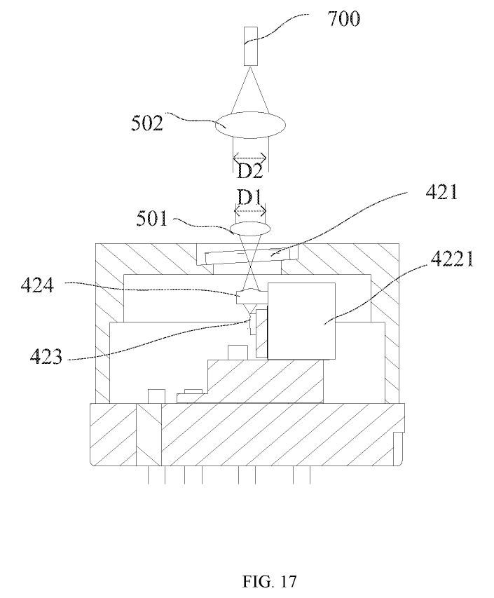

FIG. 16 is a second schematic exploded view of an optical transmitter component according to some embodiments of the present disclosure. FIG. 17 is a second schematic diagram of an optical path of an optical transmitter component according to some embodiments of the present disclosure. As shown in FIG. 16 and FIG. 17, the optical transmitter component 400 includes a header 410, a cap 420, and other devices disposed in the header 410 and the cap 420. The cap 420 covers one end of the header 410. The header 410 includes several pins 430. The pins are configured to establish electrical connections between the circuit board and other electrical devices in the optical transmitter component 400.

The optical transmitter component adopts a coaxial TO package, and includes a header and a cap covering the header. Optoelectronic devices such as an optical transmitter chip and a photodiode are placed on a surface of the header. The cap is provided with an optical window for light transmission. The header and the cap encapsulate the optical transmitter chip, the photodiode, and other optoelectronic devices in a sealed cavity.

The thermoelectric cooler 422 is generally bonded to the header with silver adhesive, to dissipate heat from the optoelectronic devices such as the optical transmitter chip 423. That is, the optical transmitter chip, the photodiode, and other optoelectronic devices are disposed on the thermoelectric cooler, and the heat generated by the optical transmitter chip, the photodiode, and other optoelectronic devices is transferred to the thermoelectric cooler for heat dissipation.

A thermally conductive block 4221 is disposed above the thermoelectric cooler 422, and the thermally conductive block 4221 is located above the thermoelectric cooler 422. The optical transmitter chip 423 is located on a sidewall of the thermally conductive block 4221. An optical output port of the optical transmitter chip 423 faces toward the optical window. The first converging lens 424 is located on the sidewall of the thermally conductive block 4221, and the first converging lens 424 is located between the optical transmitter chip 423 and the optical window.

The light emitted by the optical transmitter chip 423 is scattered light, which is converted into a converging beam after passing through the first converging lens 424. The beam after passing through the first converging lens 424 passes through the optical window and then reaches the collimating lens 501. The collimating lens 501 is configured to convert light emitted from the optical window into a collimated beam. The second converging lens 502 is located between the collimating lens 501 and an optical fiber 700, and converts a parallel beam into converged light to enter the optical fiber 700.

After passing through the first converging lens 424, light is converted into a converging beam. The focal point of the converging beam is located between the first converging lens 424 and the optical window. In the packaged optical transmitter component 400, the position of the focal point is fixed. By adjusting the distance between the collimating lens 501 and the reflecting mirror 425, the diameter D2 of the beam collimated by the collimating lens 501 can match the collimation diameter D1 of the second converging lens 502. Compared with an optical transmitter component in which emitted light is a collimated beam, the optical transmitter component according to the present disclosure can ensure that the diameter D2 of the beam collimated by the collimating lens 501 matches the collimation diameter D1 of the second converging lens 502 by adjusting the distance between the collimating lens 501 and the reflecting mirror 425.

The beam emitted by the optical transmitter chip 423 is directly transmitted to the optical window and then collimated by the collimating lens. Due to the size limitation of the optical transmitter component, the distance between the optical transmitter chip and the optical window is relatively large, resulting in the diameter of the beam collimated by the collimating lens being greater than the collimation diameter of the second converging lens 502. In the present disclosure, after passing through the first converging lens 424, light is converted into a converging beam. The focal point of the converging beam is located between the first converging lens 424 and the optical window. Within the current size range, the diameter D2 of the beam collimated by the collimating lens 501 can match the collimation diameter D1 of the second converging lens 502 by adjusting the distance between the collimating lens and the optical window.

In some embodiments, the optical transmitter component further includes a conductive protrusion 426. The conductive protrusion 426 is connected to the header 410. The conductive protrusion 426 is located on one side of the thermally conductive block 4221. A transmitter layer is disposed on a surface of the conductive protrusion. One end of the transmitter layer is connected to the pin. The transmitter layer is further connected to the optical transmitter chip and is configured to transmit the electrical signal to the optical transmitter chip.

Since all of the above embodiments are described with reference to and in combination with other embodiments, different embodiments share the same parts. For the same or similar parts among the various embodiments in this specification, mutual reference may be made. Detailed descriptions will not be provided herein.

What is claimed is:

1. An optical module, comprising:
an upper shell;
a lower shell, covering the upper shell to form a cavity; and
a circuit board, located in the cavity and comprising an upper conductive layer, a lower conductive layer, and an intermediate conductive layer located between the upper conductive layer and the lower conductive layer of the circuit board,
wherein the upper conductive layer is provided with:
a first power supply pin, configured to be connected to a first terminal of a host computer;
a second power supply pin, configured to be connected to a second terminal of the host computer, and having a same voltage as the first power supply pin; and
a dummy pin, located between the first power supply pin and the second power supply pin, wherein there is a gap between the first power supply pin and the dummy pin; there is a gap between the second power supply pin and the dummy pin;
the intermediate conductive layer is provided with a power supply line; the second power supply pin is connected to the power supply line; and
the dummy pin is connected to the power supply line.

2. The optical module according to claim 1, wherein a third through hole is formed below the second power supply pin, and the third through hole has one end connected to the second power supply pin and the other end connected to the power supply line; and
a first through hole is formed below the dummy pin, and the first through hole has one end connected to the dummy pin and the other end connected to the power supply line.

3. The optical module according to claim 2, wherein an area of the gap between the second power supply pin and the dummy pin is less than an area of an energized surface of the first terminal.

4. The optical module according to claim 2, wherein a distance of the gap between the second power supply pin and the dummy pin is less than a distance at a contact portion between the first terminal and the circuit board.

5. The optical module according to claim 2, wherein a fourth through hole is formed below the first power supply pin, and the fourth through hole has one end connected to the first power supply pin and the other end connected to the power supply line.

6. The optical module according to claim 5, wherein an area of the gap between the first power supply pin and the dummy pin is less than an area of an energized surface of the first terminal.

7. The optical module according to claim 5, wherein a distance of the gap between the first power supply pin and the dummy pin is less than a distance at a connection portion between the first terminal and the circuit board.

8. The optical module according to claim 2, wherein the intermediate conductive layer comprises a first intermediate layer, a second intermediate layer, a third intermediate layer, a fourth intermediate layer, and a fifth intermediate layer arranged in sequence; and the power supply line is located in any one of the second intermediate layer, the third intermediate layer, the fourth intermediate layer, or the fifth intermediate layer.

9. The optical module according to claim 8, wherein the power supply line is located in the fifth intermediate layer;
the first through hole comprises a first sub-hole and a second sub-hole, and a first connecting line is disposed between the first sub-hole and the second sub-hole;
the first sub-hole penetrates through the first intermediate layer and reaches the second intermediate layer; the second sub-hole is in communication with the second intermediate layer, penetrates through the third intermediate layer and the fourth intermediate layer, and reaches the fifth intermediate layer; and one end of the first sub-hole is connected to the dummy pin, and one end of the second sub-hole is connected to the power supply line.

10. The optical module according to claim 9, wherein the third through hole comprises a fifth sub-hole and a sixth sub-hole;
the fifth sub-hole penetrates through the first intermediate layer and reaches the second intermediate layer;
the sixth sub-hole starts from the second intermediate layer, penetrates through the third intermediate layer and the fourth intermediate layer, and reaches the fifth intermediate layer; and
a third connecting line is disposed between the fifth sub-hole and the sixth sub-hole, and the third connecting line is disposed in the second intermediate layer.

11. The optical module according to claim 1, wherein the power supply line is connected to a soft-start circuit, and the soft-start circuit is configured to enable delayed power-on of the optical module.

12. The optical module according to claim 2, wherein the dummy pin comprises a first dummy pin and a second dummy pin, and
the second power supply pin, the first dummy pin, the second dummy pin, and the first power supply pin are sequentially arranged and not in communication with one another.

13. The optical module according to claim 12, wherein a first through hole is formed below the first dummy pin, and the first through hole has one end connected to the first dummy pin and the other end connected to the power supply line; and
a second through hole is formed below the second dummy pin, and the second through hole has one end connected to the second dummy pin and the other end connected to the power supply line.

14. The optical module according to claim 13, wherein
an area of a gap between the second power supply pin and the first dummy pin is less than an area of an energized surface of the first terminal;
an area of a gap between the first dummy pin and the second dummy pin is less than the area of the energized surface of the first terminal; and
an area of a gap between the second dummy pin and the first power supply pin is less than the area of the energized surface of the first terminal.
